(19) United States
(12) Patent Application Publication
(10) Pub. No.: US 2026/0230073 A1
(43) Pub. Date: Aug. 6, 2026

(54) SWITCHING UNIT

(71) Applicant: Ellenberger & Poensgen GmbH, Altdorf (DE)

(72) Inventors: Hendrik-Christian KOEPF, Nuernberg (DE); Alexander LABS, Winkelhaid (DE); Markus MIKLIS, Schwarzenbruck (DE); Thomas REGAHL, Lauf an der Pegnitz (DE); Peter STEEGMUELLER, Nuernberg (DE)

(73) Assignee: Ellenberger & Poensgen GmbH, Altdorf (DE)

(21) Appl. No.: 19/630,660

(22) Filed: Mar. 27, 2026

Related U.S. Application Data
(63) Continuation of application No. PCT/EP2024/075545, filed on Sep. 12, 2024.

(30) Foreign Application Priority Data
Oct. 4, 2023 (DE) 10 2023 209 706.0

(51) Int. Cl. H03K 17/60; H03K 17/687

(52) U.S. Cl. CPC H03K 17/60; H03K 17/687

(57) ABSTRACT

A switching unit having a load connection and an earth connection, between which a switching element is connected. A semiconductor switch comprising two connections and a control input is also provided. A connection is connected to the earth connection and the other is connected to a signal contact, and the control input is connected to the load connection. An electrical circuit is also provided.

This nonprovisional application is a continuation of International Application No. PCT/EP2024/075545, which was filed on September 12, 2024, and which claims priority to German Patent Application No. 10 2023 209 706.0, which was filed in Germany on October 4, 2023, and which are both herein incorporated by reference.

### BACKGROUND OF THE INVENTION

### Field of the Invention

The present invention relates to a switching unit having a load connection and a ground connection, between which a switching element is connected. The invention also relates to an electric circuit.

### Description of the Background Art

Installations, such as industrial installations, customarily have one or more actuators by means of which an activity is carried out. In the case of an industrial installation, for example, creation and/or processing of a workpiece is carried out by means of the actuator. In order for the actuator to be operated in accordance with the desired function, a controller is provided by which means a supply of power to the actuator is regulated. In the simplest case, a switching element is present here that is actuated by means of the controller. Switching on and switching off of the actuator are accomplished by means of the switching element in this case. The switching element is incorporated in an electrical supply line of the actuator for this purpose.

If functions that could cause a hazard to other machines and/or operating personnel are carried out by means of the actuator, it is necessary to provide functional safety. Thus, in an emergency the intended function of the actuator should be terminated and a safe state should be entered. For this purpose, it is generally necessary for the supply of power to the actuator to be terminated, and therefore the switching element is open. It is also necessary during maintenance of the actuator, for example, that the actuator is not operated, or in other words for the switching element to be open. In both use cases, it is therefore necessary to ensure that the actuator is not powered in order to preclude further hazard.

In principle, a measuring of the electric current that is currently being carried by the supply line is possible for this purpose. However, relatively high electric currents and/or voltages are usually carried by these lines, so a measuring device of this nature is relatively costly. Also, the measuring device could be damaged if there is damage to the actuator and feedback into the supply line. Consequently, it would not be possible to reliably determine whether the actuator is no longer actually being supplied with power.

In order to verify whether the actuator is currently being powered, the switching state of the switching element can also be verified. Generally, a mechanical switch that has two contacts that can move relative to one another, one of which is generally attached to a movably supported contact bridge, is used as a switching element. When the switching element is electrically conductive, the contacts rest mechanically on one another, and they carry the electric current used to power the actuator. To open the switching element, the contacts are separated from one another, for which purpose the contact bridge is moved.

An auxiliary contact customarily is attached to the contact bridge. When the contact bridge is moved, the auxiliary contact is disconnected from a different auxiliary contact, and a flow of current through an auxiliary circuit in which the auxiliary contacts are incorporated is interrupted. By verification of whether a flow of current is present in the auxiliary circuit, it is therefore possible to assess whether the switching element is open or closed. In this case, a reduced electric current can be carried by the auxiliary circuit and/or a reduced voltage can be applied, and thus verification of the auxiliary circuit is simplified. In addition, the auxiliary circuit can be galvanically isolated from the supply line in this case, which further increases safety.

With this method of verifying the switching state of the switching element, it is necessary to use a relatively complex mechanical switch that has at least the two auxiliary contacts in addition. The use of a semiconductor switch is not possible, however, since two mutually separate electric circuits cannot be opened simultaneously by means thereof. On account of the use of the mechanical switch, during opening in this design the formation of an arc is possible, which leads to welding of the contact, for example, so that it can no longer be opened. In addition, manufacturing costs are relatively high.

### SUMMARY OF THE INVENTION

It is therefore an object of the present invention to specify an especially suitable switching unit as well as an especially suitable electric circuit, wherein manufacturing costs advantageously are reduced, and wherein, in particular, safety is increased.

The switching unit can be, for example, a component part of an installation by means of which a specific function is carried out. In particular, the installation is an industrial installation and serves to produce and/or process a particular workpiece, for example. For this purpose, the installation has an actuator, in particular. The actuator is, e.g., an electric motor that is a rotating electric motor or a linear motor, for example. Alternatively, the actuator is a valve that is electrically actuated, for example. In another alternative, the installation is a communications system or a computing center, for example.

The switching unit in this case is suitable, in particular intended equipped to interrupt or to establish a flow of electric current. In this case, the electric current that is carried in the normal case and, in particular, corresponds to the rated current, is preferably between 0.5 A and 200 A, between 1 A and 100 A, or between 10 A and 50 A. Preferably, a rated voltage of the switching unit, which, in particular, is applied thereto when the switching unit is not electrically nonconductive is greater than 10 V, 20 V, or 100 V and, for example, is less than 10 kV, 5 kV, or 1 kV. In particular, the voltage is a DC voltage or an AC voltage.

The switching unit has a load connection and a ground connection, between which a switching element is connected. If the switching element is electrically conductive, which is to say closed, the load connection and the ground connection make low-resistance contact with one another. When the switching element is open, and thus is in the electrically nonconductive state, the load connection and the ground connection are connected to one another only with high resistance, however, so that a flow of electric current between them is not possible. The ground connection in this case is suitable, in particular is intended and equipped, for a ground potential to be applied thereto. The load connection, on the other hand, is suitable, in particular is intended and equipped, for a load to be connected thereto. In the installed state, the load connection is electrically connected through the load to a voltage source. In this case, a supply of power to the load takes place when the switching element is electrically conductive, which is to say closed. If, in contrast, the switching element is open, a supply of power to the load is interrupted.

For example, the switching element can be a mechanical switch, such as a relay. Preferably, however, the switching element is designed as a semiconductor switch and has, in particular, a relatively high current carrying capacity. Expediently, the switching element is a field-effect transistor, preferably a MOSFET, IGBT, or GTO.

The switching unit can include a semiconductor switch that is separate from the switching element. In other words, the semiconductor switch is a separate component from the switching element, and the semiconductor switch is provided by means of a semiconductor device. The semiconductor switch has two connections that are connected to one another with low resistance when the semiconductor switch is electrically conductive. If, in contrast, the semiconductor switch is open, the two connections are connected to one another with high resistance. Furthermore, the semiconductor switch has a control input. By applying a specific electric potential to the control input, it is possible in this case to shift the semiconductor switch into the electrically conductive or into the electrically nonconductive state. The semiconductor switch expediently is a transistor. At least, the semiconductor switch preferably has a lower current carrying capacity than the switching element so that manufacturing costs are reduced.

A connection of the semiconductor switch can be routed to the ground connection. The other connection is routed to a signal contact of the switching unit. Preferably, the connection in this case makes direct electrical contact with the signal contact without one or more additional electrical/electronic components, at least some of which are, e.g., electrically connected in series and/or in parallel with one another, being arranged between them. When the semiconductor switch is electrically conductive, the signal contact is therefore at the same electric potential as the ground connection, which is to say, in particular, is electrically grounded, or at least is at an electric potential that is determined by ground. When the semiconductor switch is open, in contrast, the electric potential of the signal contact is different from ground and/or, in particular, is independent thereof.

The control input of the semiconductor switch can be routed to the load connection. For example, in this case the control input is electrically connected directly to the load connection, or additional electrical/electronic components are arranged between them. At least the electric potential present at the control input is dependent on the electric potential present at the load connection.

If, therefore, the switching element is electrically closed, then the load connection is at the same electric potential as the ground connection. Consequently, an electric potential corresponding to the ground connection is applied to the control input, and the semiconductor switch is designed, in particular, such that it is then open. As a result, the electric potential of the signal contact is different from ground. If, in contrast, the switching element is electrically nonconductive, the electric potential present at the load connection is different from the electric potential present at the ground connection. As a result, the electric potential present at the control input is also changed. In this case, the semiconductor switch is designed, in particular, such that it is then electrically conductive. Therefore, ground, in particular, is then present as the electric potential at the signal contact, or at least they correspond to one another.

In summary, on account of the interconnection it is thus possible to assess, on the basis of the electric potential present at the signal contact, whether the switching element is in the electrically conductive state or in the electrically nonconductive state. Consequently, safety is increased. In this case, the requirements on the switching element are relatively low so that manufacturing costs are reduced. Moreover, it is possible to use a semiconductor as the switching element, for which reason manufacturing costs are further reduced.

Suitably, the switching unit can include a housing in which one or more terminals are incorporated. In this case, one of the terminals expediently is electrically connected to the ground connection and the other to the load connection. Consequently, the connection of the corresponding electric potentials from outside the housing is made possible, which simplifies installation. Alternatively or in combination herewith, the signal contact, for example, is at least indirectly observable from outside the housing.

For example, the switching element can be designed as a mechanical switch that, for example, is only manually actuatable. Alternatively thereto, the switching element has, for example, a driving input through which an actuation of the switching unit is accomplished. Expediently, the switching state of the switching element can be changed as a function of an electric potential present at the driving input in this case. Consequently, it is possible to set the flow of electric current between the load connection and the ground connection remotely from the switching unit, in particular within the framework of process control. Preferably, the switching element is a semiconductor in this case. In an improvement, the switching unit is a component part of a circuit breaker, for example, wherein the switching element is, in particular, actuated as a function of a fault condition, as for example an overcurrent, a short-circuit current, an overvoltage, or another malfunction, for example of the possible load.

Preferably, the signal contact can be routed to a first resistor. In this case, an additional electric component is arranged between the signal contact and the first resistor, in particular, or the signal contact is electrically connected directly to the first resistor. It is ensured by means of the first resistor, in particular, that the electric current carried by the semiconductor switch, when it is electrically conductive, is relatively low. Consequently, safety is increased, and electrical losses are reduced. Moreover, loading of the switching element is further reduced in this way so that the element can be designed relatively economically.

For example, the first resistor can be routed to a supply connection. In the installed state/during use of the switching unit, an electric potential is preferably present at the supply connection that suitably is constant over time. In this case, the voltage applied, in particular between the ground connection and the supply connection, is lower than 50 V, 20 V, 10 V, or 5 V. Consequently, the requirements on the first resistor, the signal contact, and the semiconductor switch are further reduced, and therefore manufacturing costs can be reduced. Expediently, the switching unit in this case includes a terminal that is electrically connected to the supply connection, and in particular is incorporated in the possible housing. Consequently, it is possible to apply the corresponding electric potential to the supply connection from outside the housing.

Preferably, a control unit can be present that is electrically connected to the supply connection. Consequently, this is also operated on the basis of the electric potential applied there. Consequently, a susceptibility to faults is reduced and an operation of the control unit is possible that is independent of the voltage present between the ground connection and the load connection. Preferably, the switching element is actuated by means of the control unit in this case.

In an alternative thereto, the first resistor can be routed to the load connection through a second resistor. Consequently, the separate supply connection is not necessary, which simplifies installation. Also, manufacturing costs are reduced in this way. When the semiconductor switch is open, the electric potential present at the signal contact corresponds to the electric potential present at the load connection. It is ensured by means of the two resistors in this case that an electric current flowing from the load connection through the semiconductor switch to the ground connection is relatively low, so that loading of the semiconductor switch is reduced. It is also ensured in this way that no unwanted supply of power takes place to the possible load connected to the load connection when the switching element is open. On account of the series connection of the two resistors, the requirements on the individual resistors are reduced so that they can be designed to be relatively compact and economical.

Preferably, the second resistor can be routed to the ground connection through a Zener diode. In this case, the reverse direction of the Zener diode is expediently oriented away from the ground connection. Consequently, the Zener diode is connected in parallel with the series connection having the first resistor and the semiconductor switch. Also, the Zener diode is, in particular, electrically connected in parallel with the series connection having the second resistor and the switching element. A formation of an overvoltage that could lead to a destruction of the switching element or semiconductor switch is avoided by means of the Zener diode, in particular. It is ensured in this case by means of the second resistor that the maximum electric current flowing through the Zener diode is relatively low, so that a relatively economical component can be used here as well.

Preferably, the first resistor can be routed to a third resistor. In this case, the first resistor expediently is electrically connected directly to the third resistor. The third resistor, in turn, is routed to the load connection through a first diode. Furthermore, the third resistor is routed to the control input through a fourth resistor and a second diode. Expediently, the two diodes and the fourth resistor are electrically connected in series in this case. The reverse directions of the two diodes are, in particular, opposite one another, and the reverse direction of the second diode is oriented from the control input to the fourth resistor. In particular, the two diodes are identical in design to one another, and therefore manufacturing costs are reduced. A mode of operation of the switching unit is also improved in this way. Preferably, the two diodes are thermally connected to one another, and expediently are arranged next to one another. Consequently, the two diodes always have essentially the same behavior. In this case, the first resistor, for example, is routed to the supply connection so that the third resistor is also routed to the supply connection. Alternatively thereto, the second resistor is present, and the third resistor is, in particular, also routed to the second resistor.

By means of the fourth resistor and the third resistor, it is possible to set the voltage level that results in an actuation, preferably the switch-on, of the semiconductor switch. In other words, the third, fourth, and first resistors function in the manner of a voltage divider, in particular. In summary, it is consequently possible to achieve the end that the semiconductor is actuated even when a voltage that is different from 0 V arises across the switching element. Consequently, even a relatively high internal resistance can be present for the switching element, or this element can be operated in a current-limited mode. In this case, however, it is reliably signaled at the signal contact that the flow of electric current is present. The electric potential present at the signal contact changes only starting from a further increase in the voltage across the switching element.

For example, only a single switching element may be present, which preferably is bidirectional in design. Alternatively, the switching element is only unidirectional, and it therefore possible only to use the switching unit for unidirectional operation. In an improvement, a second switching element is present that expediently is identical in design to the switching element. The second switching element is connected between the ground connection and a second load connection. In this case, the third resistor is routed to the second load connection through a third diode. The reverse direction of the third diode in this case is oriented away from the second load connection, in particular. Consequently, a signaling of the switching state of the second switching element is also accomplished by means of the signal contact.

For example, the two load connections can be separate from one another in this case. Alternatively thereto, the two load connections make low-resistance electrical contact with one another, for example. Preferably, they are formed by means of a common (mechanical) terminal or the like, which is incorporated in the possible housing of the switching unit, for example. In this case, the two switching elements preferably are each unidirectional in design, and are arranged opposite one another between the ground connection and the respective load connection. Consequently, the switching unit is fit for bidirectional operation even when the two switching elements are only unidirectional in design. On account of the third diode, it is possible in this design to use only the single semiconductor switch, and therefore manufacturing costs are relatively low.

In an example, the third diode may not be present, for example, but the second switching element is. In this case, the switching unit is, in particular, at least partly mirror-imaged in design. Thus, an additional semiconductor switch is expediently present that is associated with the second switching element. The additional semiconductor switch, which suitably is identical in design to the semiconductor switch, is routed by means of its control input to the additional load connection, in particular, and the two connections of the additional semiconductor switch are routed to the ground connection and to an additional signal contact. Preferably, the latter is routed to an additional first resistor that is routed to the possible supply connection, for example. Alternatively thereto, the additional first resistor is routed to the second load connection through an additional second resistor, for example. Expediently, an additional Zener diode is present, through which the additional second resistor is routed to the ground connection. Alternatively or in combination therewith, the additional first resistor is routed to an additional third resistor, which is routed to the second load connection through an additional first diode and to the control input of the additional semiconductor switch through an additional fourth resistor and an additional second diode.

For example, the load connection can be electrically connected to the ground connection only by means of the switching element. Alternatively thereto, the switching element is bridged by means of a fourth resistor, so that the ground connection also makes electrical contact with the load connection by means of the fourth resistor. In this case, the resistance value of the fourth resistor is relatively high, so that an electric current flowing through the fourth resistor is relatively low or negligible. The individual component parts of the switching unit, in particular the possible first, second, and/or third resistors, are expediently designed such that the switchover of the switching element takes place even with a relatively low voltage present at the switching element. If the switching unit and any electric circuit in which the switching unit is used, or at least the possible load, function properly, then an electric potential is therefore always present at the control input, for which reason the electrical potential present at the signal contact corresponds to ground.

If, however, ground is present as the electric potential at the load connection, for example on account of a broken line, the semiconductor switch is open so that the electric potential present at the signal contact does not correspond to ground. If, for example, an altered voltage is present at the load connection on account of a cross-circuit / conductor fault, this can likewise be read out at the signal contact by means of an appropriate choice of the resistors. In other words, a signaling / verification of whether the conductor fault / cross-circuit is present is therefore accomplished by means of the switching unit.

The signal contact is connected to an LED, for example. The LED (light-emitting diode) is expediently incorporated in a housing of the switching unit in this case so that the LED is also visible from outside the switching unit. If the first resistor is present, the LED expediently is connected between the first resistor and the semiconductor switch, wherein expediently a contact of the LED makes electrical contact with the signal contact. The other contact of the LED, in contrast, makes electrical contact with the first resistor. Consequently, the signal contact is routed to the first resistor through the LED.

The switching unit can include the possible control unit that is routed to the signal contact. In particular, the control unit is electrically connected directly to the signal contact. During operation, a verification as to whether the switching element is electrically conductive or electrically nonconductive is accomplished by means of the control unit in this case. The control unit is, in particular, suitable, preferably is intended and equipped, for this purpose. Suitably, the control unit is connected via a signal to a communications input of the switching unit that is suitable, in particular is intended and equipped, to be connected to a higher-level controller. Communication with the controller is carried out in this case through the communications input, in particular by means of the control unit, and in particular it is reported whether the switching element is closed or open. Alternatively or in combination herewith, the switching element is also operated by means of the control unit. Consequently, it can be directly verified by means of the control unit whether the driving of the switching element has been correctly implemented, or whether a malfunction of the switching element is present, for example. For example, the control unit is discrete in construction or has, e.g., an integrated circuit.

The electric circuit has a voltage source that can include two power connections. In this case an AC voltage, for example, or preferably a DC voltage, is provided by means of the voltage source, and is consequently applied between the two power connections. In particular, the provided DC voltage is greater than 100 V. Moreover, the electric circuit has a load that is composed of an actuator, for example. In addition, the electric circuit includes a switching unit having a load connection and a ground connection, between which a switching element is connected. The switching unit further includes a semiconductor switch that has two connections and a control input. One connection is routed to the ground connection and the other to a signal contact, and the control input is routed to the load connection.

One of the power connections of the voltage source is electrically connected to ground, in particular directly. The other power connection of the voltage source, in contrast, is routed to the load. The load, in turn, is routed to the load connection. Consequently, one of the power connections is electrically connected to the load connection of the switching unit through the load. For example, only the load is present in this case, or, e.g., additional loads are also present that, for example, are electrically connected in parallel and/or in series with the load. The ground connection of the switching unit is electrically connected to ground. When the switching element is closed, a flow of electric current therefore occurs, and the load is operated. If, in contrast, the switching element is open, then the flow of electric current through the switching unit is prevented, and the load is not operated. The electric circuit is, for example, a component part of an installation, such as an industrial installation or a telecommunications system. In particular, the switching unit serves, at least in part, to provide functional safety in the electric circuit.

The improvements and advantages explained in connection with the switching unit can also be applied correspondingly to the electric circuit and vice versa.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 schematically shows an electric circuit with a load and with a switching unit, and

FIGS. 2 through 4 show an example of the switching unit in a simplified circuit diagram.

### DETAILED DESCRIPTION

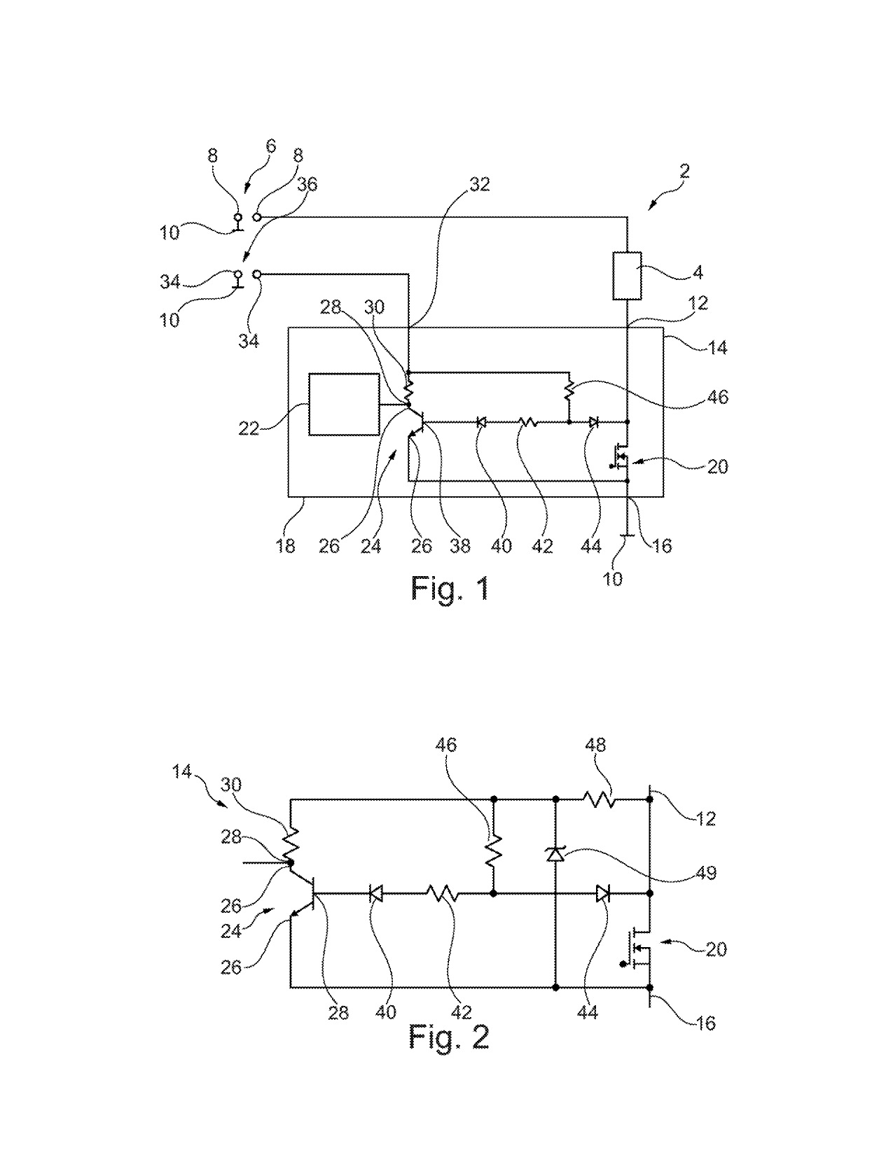

In FIG. 1, an electric circuit 2 that is part of an industrial installation is depicted in a schematically simplified representation. The electric circuit 2 includes a load 4, which is a component part of an actuator. A processing/creation of a workpiece is accomplished by means of the actuator during operation, and the load 4 is an electric motor in the example depicted. In order to operate the load 4, the electric circuit 2 includes a voltage source 6, which has two power connections 8. The voltage source 6 is provided by means of a rectifier, and a DC voltage of several hundred V is applied between the power connections 8.

One of the power connections 8 is electrically routed to ground 10, namely is electrically connected directly to ground 10. The other power connection 8 is routed to the load 4. The load 4 is additionally routed to a load connection 12 of a switching unit 14 so that the load 4 is electrically connected between the load connection 12 and one of the power connections 8. The switching unit 14 also includes a ground connection 16, which is electrically connected directly to ground 10. Consequently, the ground connection 16 has the same electric potential as one of the power connections 8. The load connection 12 and the ground connection 16 include terminals, which are incorporated in a housing 18 of the switching unit 14.

Connected between the load connection 12 and the ground connection 16 is a switching element 20 that is arranged in the housing and is designed as a MOSFET. If the switching element 20 is driven such that it is electrically conductive, the load connection 12 and the ground connection 16 are connected to one another with low resistance. Consequently, a flow of electric current from one of the power connections 8 through the load 4 and the switching unit 14 to ground 10 is possible. As a result, the load 4 is operated. If, in contrast, the switching element 20 is driven such that it is electrically nonconductive, the flow of current is interrupted and the load 4 is not operated.

Driving of the switching element 20 is accomplished by means of a control unit 22, which likewise is arranged in the housing 18. The control unit 22 is connected via a signal to a communications input, which likewise is incorporated in the housing 18. By means of the communications input, the control unit 22 is connected to a higher-level controller of the electric circuit 2 so that the actuator is operated by means thereof. In this case, whether the load 4 should be operated or not is specified by means of the controller, and the switching element 20 is driven accordingly, which is to say opened or closed, by means of the control unit 22. For this purpose, a corresponding electric potential is applied to a driving input of the switching element 20 by means of the control unit 22. However, it is possible that the switching state of the switching element 20 does not match the specification on account of a malfunction, for example material fatigue or aging.

For verification of the actual switching state of the switching element 20, the switching unit 14 therefore includes a semiconductor switch 24, which is designed as a transistor. The semiconductor switch 24 has two connections 26, of which one is routed to the ground connection 16. Here, this connection 26 makes direct electrical contact with the ground connection 16, and consequently always has ground 10 as electric potential. The other connection 26 is routed to a signal contact 28 and is electrically connected directly thereto. The signal contact 28, in turn, is electrically connected directly to the control unit 22, which has an integrated circuit.

The signal contact 28 is furthermore routed to a first resistor 30, and for this purpose is electrically connected directly to the same. The first resistor 30, in turn, is routed to a supply connection 32, and electrically connected directly to the same. Consequently, the supply connection 32 is connected to one of the connections 26 of the semiconductor switch 24 through the first resistor 30 and the signal contact 28. The supply connection 32 includes a terminal that is incorporated in the housing 18 and that is electrically connected to a second power connection 34 of a second voltage source 36 by means of a line. The second voltage source 36 has a total of two second power connections 34, wherein the remaining power connection 34 is electrically connected directly to ground 10. Here, a DC voltage of 12 V is provided by means of the second voltage source 36 and is applied between the two second voltage sources 34.

The control unit 22 in this case likewise makes electrical contact with the supply connection 32 and the ground connection 16 so that electrical supply of the control unit 22 is accomplished by means of the second voltage source 36.

The semiconductor switch 24 further has a control input 38, wherein the two connections 26 are electrically connected either with low resistance or with high resistance, depending on the electric potential present at the control input 38. In other words, the semiconductor switch 24 is open or closed as a function of the applied electric potential. The control input 38 is routed to, and is electrically connected directly to, the load connection 12 through a second diode 40, a fourth resistor 42, and a first diode 44.

The two diodes 40, 44 are identical in design to one another and are arranged directly next to one another mechanically, so that they are thermally connected to one another. Consequently, the two diodes 40, 44 have the same temperature and, therefore, always have essentially the same behavior. In this case, the reverse directions of the two diodes 40, 44 are opposite one another, wherein the reverse direction of the second diode 40 is oriented away from the control input 38. On the other hand, the reverse direction of the first diode 44 is oriented away from the load connection 12. The switching unit 14 further includes a third resistor 46, by which means the first resistor 30 is routed to the first diode 44 and the fourth resistor 42.

If the switching element 20 is shifted into the electrically conductive state by means of the control unit 22, then ground 10, essentially, is present as the electric potential at the load connection 12. An adjustment follows solely on account of an internal resistance of the switching element 20 that is relatively low. As a result, an electric current flows from one second power connection 34 primarily through the third resistor 46, the first diode 44, and the switching element 20 to ground 10. On account of the dimensioning of the second resistor 46, it is ensured in this case that only relatively low electric currents flow, so that electrical loss is small. At least essentially no flow of current takes place through the fourth resistor 42 and the second diode 40, and essentially ground 10 is present as the electric potential at the control input 38, wherein an adjustment is on account of the fourth resistor 44. Consequently, the semiconductor switch 24 is open. As a result, the signal contact 28 has the electric potential of the associated second power connection 34 as its electric potential, wherein an adjustment is possible on account of the first resistor 30. At least the electric potential is different from ground 10.

If the switching element 20 is open, the flow of electric current from the associated second power connection 34 to ground 10 is not possible through the switching element 20, for which reason the electric potential at the control input 38 is increased. This potential corresponds essentially to that of the associated second power connection 34, wherein an adjustment takes place on account of the second diode 40, the fourth resistor 42, and the third resistor 46. In this case, it is ensured by means of the first diode 44 that the voltage source 6 has no effect on the switching state of the semiconductor switch 24. On account of the increased electric potential present at the control input 38, the semiconductor switch 24 is closed so that the two connections 26 are connected to one another with low resistance. As a result, a flow of electric current takes place from the associated second power connection 34 through the supply connection 32, the first resistor 30, the semiconductor switch 24, and the ground connection 16 to ground 10. It is ensured in this case by means of appropriate selection of the first resistor 30 that an electric current that flows is relatively low here, as well. However, on account of the closed semiconductor switch 24, the electric potential of the signal contact 28 is equal to ground 10, wherein a slight adjustment may potentially be present on account of the internal resistance of the semiconductor switch 24.

The dimensioning of the resistors 30, 46, 42 in this case is such that the electric currents that flow are always relatively low on the one hand. On the other hand, they are chosen such that a change in the electric potential of the signal contact 28 takes place depending on whether the switching element 20 is electrically conductive or electrically nonconductive.

The switching state of the switching element 20 is set during operation by means of the control unit 22. Subsequently, the electric potential present at the signal contact 28 is sensed, and whether the switching state of the switching element 20 corresponds to the setting is verified on the basis thereof. If a difference is present, a warning message is issued through the communications input, and the switching element 20 is shifted to the electrically nonconductive state. As a result, an attempt is made to shut down the load 4 and transfer it to a safe state.

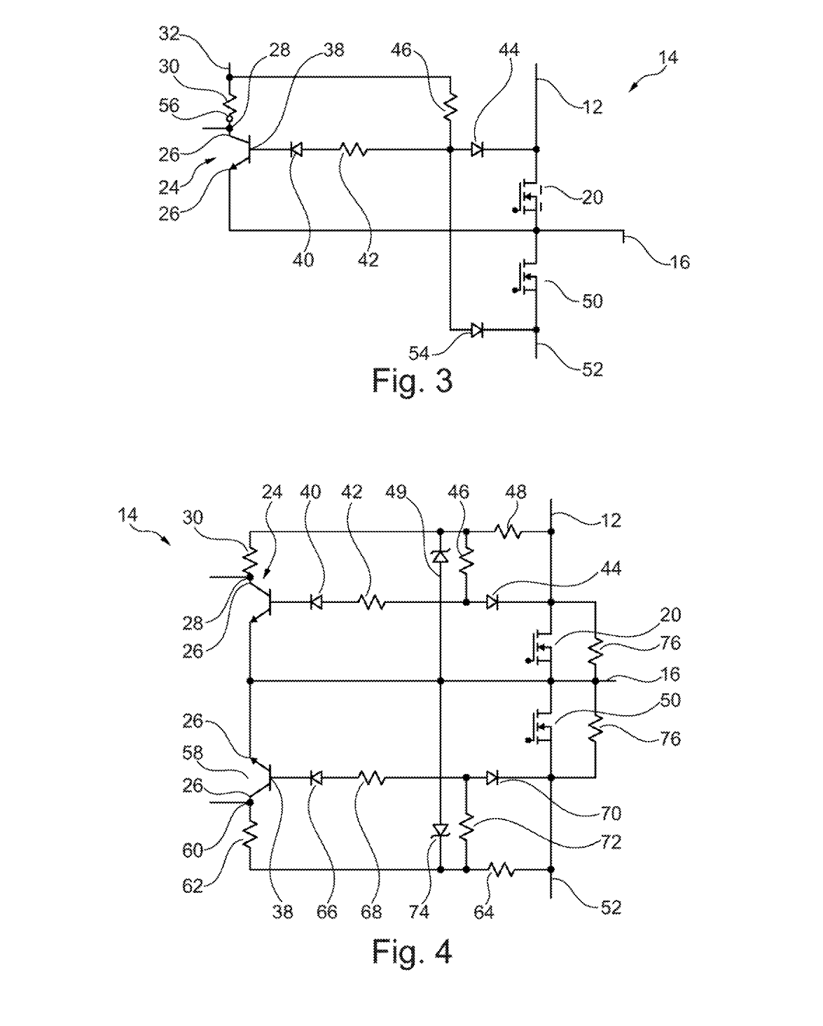

In FIG. 2, a modification of the switching unit 14 is depicted. The switching element 20 that is connected between the ground connection 16 and the load connection 12 is not changed. The semiconductor switch 24 with the two connections 26, of which one makes electrical contact with the ground connection 16, is also still present. The other connection 26 makes electrical contact, through the signal contact 28, with the first resistor 30, which also is still routed to the first diode 44 and the fourth resistor 42 by means of the third resistor 46. The fourth resistor 42 is likewise connected between the first diode 44 and the second diode 40, which is electrically connected to the control input 38. Also, the first diode 44 is still routed to the load connection 12. The control unit 22 and the housing 18 are also still present.

In an example, the supply connection 32 is no longer present. Instead, the first resistor 30 is routed to the load connection 12 through a second resistor 48. In this design, the third resistor 46 is connected between the second resistor 48 and the fourth resistor 42. When the switching element 20 is open, an electric potential that corresponds to the electric potential of the power connection 8, which is associated with the load connection 12 is therefore applied to the control input 38, wherein an adjustment takes place on account of the load 4, the second resistor 48, the third resistor 46, and the fourth resistor 42. The resistors 42, 46, 48 in this design are chosen such that an overloading of the semiconductor switch 24 is precluded, and in this case the semiconductor switch 24 is closed. When the semiconductor switch 24 is closed, the electric current flows from the load connection 12 through the second resistor 48 and the first resistor 30 to the ground connection 16. On account of the electrically conductive semiconductor switch 24, the electric potential of the signal contact 28 is likewise essentially equal to ground 10 in this case. Consequently, the mode of operation of this switching unit 14 corresponds essentially to that of the preceding variant, wherein the supply connection 32 is not present, and therefore the second voltage source 36 is not necessary.

Moreover, a Zener diode 49 is present, by which means the second resistor 48 is routed to the ground connection 16. The reverse direction of the Zener diode 49 is oriented toward the ground connection 16. It is ensured by means of the Zener diode 49 that a voltage present at the semiconductor switch 24 is limited so that the electric potential present at the signal contact 28 is also limited. Consequently, a destruction of the control unit 22 in the event of a malfunction of the load 4 is avoided.

Depicted in FIG. 3 is another modification of the switching unit 14, which has all the component parts of the variant depicted in FIG. 1. In addition, a second switching element 50 is present, which is identical in design to the switching element 20. The second switching element 50 is connected between a second load connection 52 and the ground connection 16. In this design, the forward directions of the two switching elements 20, 50 are different so that the switching unit 14, unlike the variant shown in FIG. 1, is designed to be bidirectional. Furthermore, a third diode 54 is present, wherein the third resistor 46 is routed to the second load connection 52 through the third diode 54. In this design, the fourth resistor 42 is routed to the second load connection 52 through the third diode 54, and the reverse direction of the third diode 54 is oriented away from the second load connection 52.

Consequently, depending on the direction of current or which load connection 12, 52 the load 4 is connected to, the semiconductor switch 24 is always reliably actuated when the two switching elements 20, 50 are open, so that the electric potential present at the signal contact 28 is changed.

Moreover, an LED 56 is connected between the signal contact 28 and the first resistor 30. In this case, the signal contact 28 is routed to the LED 56. If the semiconductor switch 24 is electrically conductive, the LED 56 is powered so that it lights up. If the semiconductor switch 24 is open, the LED 56 does not light up. Consequently, the switching state of the two switching elements 20, 50 is likewise signaled by means of the LED 56. The LED 56 is placed in an opening in the housing 18 in this design so that the switching state is visible from outside the housing 18.

In FIG. 4, another variant of the switching unit 14 is shown. This variant corresponds essentially to the example shown in FIG. 2, although it is mirror-imaged for the most part. Consequently, this variant has all the component parts of the example shown in FIG. 2, wherein the second switching element 50, which is connected between the ground connection 16 and the second load connection 52, is additionally present. Furthermore, an additional semiconductor switch 58 is present, which is identical in design to the semiconductor switch 24. It therefore also has the two connections 26, of which one is electrically connected to the ground connection 16. The other connection 26 makes electrical contact with the second load connection 52, through an additional signal contact 60 having an additional first resistor 62, which is identical in design to the first resistor 30, and an additional second resistor 64, which is identical in design to the second resistor 48.

The control input 38 of the additional semiconductor switch 58 makes electrical contact with the second load connection 52 through an additional second diode 66, an additional fourth resistor 68, and an additional first diode 70. These are identical in design to the second diode 40, the fourth resistor 42, and the first diode 44, respectively. Also, an additional third resistor 72 is present, which is identical in design to the third resistor 46, and its arrangement corresponds to the arrangement of the third resistor 46. Also, an additional Zener diode 74 is present, by means of which the additional second resistor 64 is routed to the ground connection 16. In summary, this arrangement corresponds essentially to the bidirectionally designed variant of FIG. 2. In addition, the two switching elements 20, 50 are bridged with fourth resistors 76 that are identical in design. The two fourth resistors 76 are designed with high resistance so that power dissipation remains low.

The mode of operation of the switching unit 14 corresponds essentially to that of the variant depicted in FIG. 2, and when the two switching elements 20, 50 are open, the electric potential present at the signal contacts 28, 60 is increased. If a cross-circuit / conductor fault is present, the electric potential is changed at least slightly at one of the two load connections 12, 52 in comparison with the other. Consequently, a flow of electric current is possible between the two load connections 12, 52, namely through the fourth resistors 46. As a result, the electric potential present at the control inputs 38 is reduced, so that the semiconductor switches 24, 58 are shifted to the electrically nonconductive state. Consequently, the electric potential present at the signal contacts 28, 60 is increased, which is sensed by means of the control unit 22. Consequently, this variant of the switching unit 14 is fit for sensing a cross-circuit / conductor fault. The design of the individual electric components of the switching unit 14 is adapted accordingly in this design.

The invention is not limited to the examples described above. Instead, other variants of the invention can also be derived herefrom by the person skilled in the art without departing from the subject matter of the invention. Moreover, all individual features described in connection with the individual examples can, in particular, also be combined with one another in other ways without departing from the subject matter of the invention.

What is claimed is:

1. A switching unit comprising:
a load connection; and
a ground connection;
a switch arranged between the load connection and the ground connection; and
a semiconductor switch that has two connections and a control input, wherein one of the two connections is routed to the ground connection and the other connection of the two connections is routed to a signal contact, the control input being routed to the load connection.

2. The switching unit according to claim 1, wherein the signal contact is routed to a first resistor.

3. The switching unit according to claim 2, wherein the first resistor is routed to a supply connection.

4. The switching unit according to claim 2, wherein the first resistor is routed to the load connection through a second resistor.

5. The switching unit according to claim 4, wherein the second resistor is routed to the ground connection through a Zener diode.

6. The switching unit according to claim 2, wherein the first resistor is routed to a third resistor, which is routed to the load connection through a first diode and to the control input through a fourth resistor and a second diode.

7. The switching unit according to claim 6, further comprising a second switch that is connected between the ground connection and a second load connection, wherein the third resistor is routed to the second load connection through a third diode.

8. The switching unit according to claim 1, wherein the switch is bridged via a fourth resistor.

9. The switching unit according to claim 1, wherein the signal contact to an LED is connected and/or is routed to the control unit.

10. An electric circuit comprising:
a load;
a voltage source that has two power connections; and
the switching unit according to claim 1,
wherein one of the two power connections is electrically connected to ground and the other power connection of the two power connections is routed to the load that is routed to the load connection, and
wherein the ground connection is electrically connected to ground.
